(19) United States
(12) Patent Application Publication
(10) Pub. No.: US 2007/0235839 A1
(43) Pub. Date: Oct. 11, 2007

(54) Semiconductor devices utilizing AlGaAsP

(75) Inventors: Mark Andrew DeVito, Vancouver, WA (US); Paul Andrew Crump, Portland, OR (US); Jun Wang, Vancouver, WA (US); Weimin Dong, Vancouver, WA (US); Michael Peter Grimshaw, Vancouver, WA (US); Christopher B. Ebert, Washougal, WA (US)

Correspondence Address: PATENT LAW OFFICE OF DAVID G. BECK, P. O. BOX 1146, MILL VALLEY, CA, 94942, US

(73) Assignee: nLight Photonics Corporation, Vancouver, WA (US)

(21) Appl. No.: 11/246,346

(22) Filed: Oct. 7, 2005

Related U.S. Application Data
(63) Continuation-in-part of application No. 11/212,420, filed on Aug. 24, 2005.

(51) Int. Cl. H01L 29/20; H01L 21/00

(52) U.S. Cl. 257/615; 438/46; 438/93

(57) ABSTRACT

A method of minimizing stress within large area semiconductor devices which utilize a GaAs substrate and one or more thick layers of AlₓGa₁₋ₓAs is provided, as well as the resultant device. In general, each thick AlₓGa₁₋ₓAs layer within the semiconductor structure is replaced, during the structure's fabrication, with an AlₓGa₁₋ₓAs_{z}P_{1-z} layer of approximately the same thickness and with the same concentrations of Al and Ga. The AlₓGa₁₋ₓAs_{z}P_{1-z} layer is lattice matched to the GaAs substrate by replacing a small percentage of the As in the layer with P.

### CROSS-REFERENCE TO RELATED APPLICATION

This application is a continuation-in-part of U.S. patent application Ser. No. 11/212,420, filed Aug. 24, 2005, the disclosure of which is incorporated herein by reference for any and all purposes.

### REFERENCE TO GOVERNMENT CONTRACT

This invention was made with U.S. Government support under Grant No. MDA972-03-C-0101 awarded by DARPA. The United States Government has certain rights in this invention.

### FIELD OF THE INVENTION

The present invention relates generally to semiconductor devices and, more particularly, to a device design and fabrication method for controlling stress in a semiconductor device. BACKGROUND OF THE INVENTION

There is a degree of strain built into many semiconductor devices, the strain due both from the selected manufacturing process (e.g., selected deposition technique and associated parameters) and from lattice mismatch between materials. FIG. 1 graphically illustrates the relationship between the lattice constant, i.e., atomic spacing, and the bandgap for a variety of compound semiconductor materials. As a result of the differences in lattice constant, growing a semiconductor material from the left side of line 103 (e.g., GaP, AlP, etc.) onto a GaAs substrate will result in a tensile strain within the as-grown material while growing a semiconductor on the right side of line 103 (e.g., InP, GaSb, InAs, etc.) on the same substrate will result in a compressive strain within the as-grown material.

In some instances a material may be purposefully strained during growth in order to control a particular quality of the final device, for example to match the band gap of a solar cell or solar cell layer to a particular wavelength within the solar spectrum. If the portion of the device that is strained is very thin, on the order of 10 nanometers, then the strain within the region will have little effect on the overall structure. In contrast, stress within the bulk materials of the semiconductor structure can have a significant effect on the overall structure. For example, the deposition of a 3.5 micron layer of AlₓGa₁₋ₓAs on a 1 centimeter wide, 1 millimeter long, 140 micron thick GaAs substrate will impart sufficient compressive stress to the material to cause a curvature of approximately 4 microns.

In very large area devices, the curvature which results from the deposition of thick layers of lattice mismatched material can lead to both performance issues as well as processing problems. For example, semiconductor devices which develop substantial heat during operation (e.g., high power transistors, processors, etc.) must typically be bonded to a heat sink in order to be able to operate at the power levels and durations required for most commercial applications. As the bonding process requires the semiconductor device to be flat, if it is not, for example due to the curvature imparted by a mismatched deposited layer, the flattening process will introduce a stress field into the device. Furthermore, since the bonding process is typically performed at a temperature greater than 140° C., differences between the thermal expansion coefficient of the heat sink and that of the semiconductor device cause an additional stress to be imparted to the device during cooling. The stress fields resulting from the flattening and high temperature bonding processes can lead to non-uniform, poor performance in the finished device. Additionally, independent of the final device area, curvature of the wafer induced by lattice mismatched material can lead to complications during the wafer fabrication process. As the wafer is thinned, this curvature will become significant and can lead to various issues, such as unintentional breakage, non-uniform chuck contact, non-uniform photoresist coating, or depth-of-focus limitations during photolithography steps. Accordingly it is clearly advantageous to eliminate, or at least reduce, these induced stress fields.

In some instances, a bulk layer material can be selected which, in combination with the selected substrate, does not suffer from the above-noted stress fields. For example, assuming a bulk layer of InGaAsP deposited on GaAs, there is a wide range of available band-gaps and lattice constants (see region 201 of FIG. 2). As such, for many desired device configurations it is possible to select a composition for a bulk layer of InGaAsP which will result in a flat device. Alternately it is possible to pick an InGaAsP composition that places the device under tensile strain, thus mitigating the stress imparted by another processing step (e.g., the bonding process). Unfortunately not every desirable bulk material allows such latitude in selection. For example, device structures fabricated with bulk layers of AlₓGa₁₋ₓAs are naturally slightly compressive when grown on a GaAs substrate. Thus with this combination of materials, the device designer is not given a choice in material stress and thus can not design a device that limits the impact of the bonding stress on the device's performance (see line 301 of FIG. 3).

Accordingly, what is needed in the art is a design and fabrication process that can be used to achieve the benefits of an AlₓGa₁₋ₓAs/GaAs structure without incurring the poor performance and processing problems that result from the two materials having different lattice constants. The present invention provides such a design and fabrication process.

### SUMMARY OF THE INVENTION

The present invention provides a method of minimizing stress within large area semiconductor devices (i.e., greater than 0.25 square millimeters) which utilize a GaAs substrate and one or more thick (i.e., greater than 0.2 microns) layers of AlₓGa₁₋ₓAs. In general, each thick AlₓGa₁₋ₓAs layer within the semiconductor structure is replaced, during the structure's fabrication, with an AlₓGa₁₋ₓAs_{z}P_{1-z} layer of approximately the same thickness and with the same concentrations of Al and Ga. Unlike the AlₓGa₁₋ₓAs layer, however, the AlₓGa₁₋ₓAsP_{1-z} layer is lattice matched to the GaAs substrate by replacing a small percentage (i.e., less than 4 percent) of the As in the layer with P. In another aspect of the invention, a large area semiconductor device comprised of a GaAs substrate and one or more thick layers of AlₓGa₁₋ₓAs_{z}P_{1-z} is provided, the AlₓGa₁₋ₓAs_{z}P_{1-z} layers being lattice matched to the GaAs substrate.

A further understanding of the nature and advantages of the present invention may be realized by reference to the remaining portions of the specification and the drawings.

### BRIEF DESCRIPTION OF THE DRAWINGS

FIG. 1 illustrates the relationship between the lattice constant and the emission wavelength/bandgap for a variety of compound semiconductor materials commonly used in the fabrication of semiconductor devices;

FIG. 2 illustrates the range of lattice constants and bandgaps available for a bulk layer of InGaAsP grown on GaAs;

FIG. 3 illustrates the range of lattice constants and bandgaps available for a bulk layer of AlₓGa₁₋ₓAs grown on GaAs;

FIG. 4 illustrates the range of lattice constants and bandgaps available for a bulk layer of AlₓGa₁₋ₓAs_{z}P_{1-z} grown on GaAs;

FIG. 5 illustrates the phase diagram for AlₓGa₁₋ₓAs_{z}P_{1-z};

FIG. 6 is an illustration of a solar cell epitaxial structure; and

FIG. 7 is an illustration of an APD epitaxial structure.

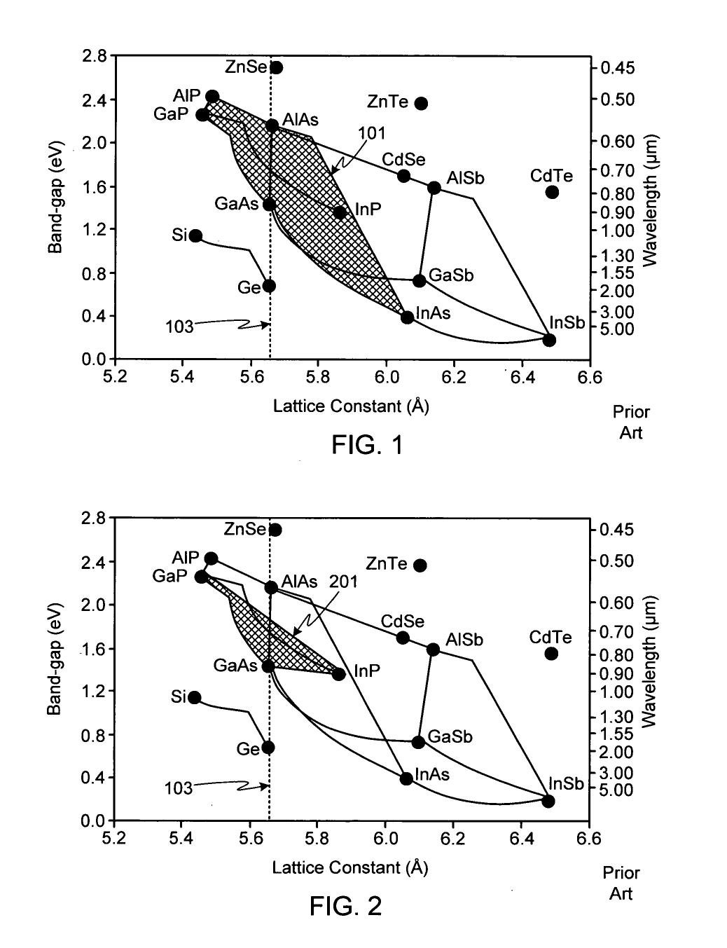

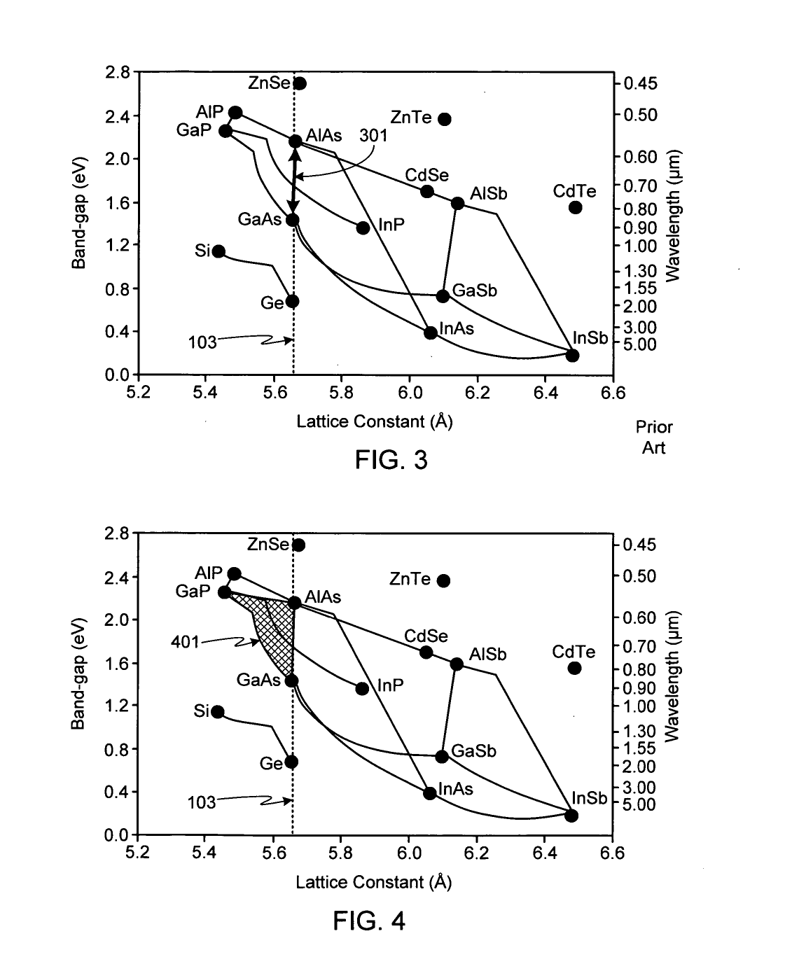

### DESCRIPTION OF THE SPECIFIC EMBODIMENTS

In order to overcome the afore-described problems, the present inventors have found that the inclusion of small amounts of phosphorous in AlₓGa₁₋ₓAs allow the lattice constant of the new material to be varied such that the stress field within a structure containing the AlₓGa₁₋ₓAs_{z}P_{1-z} layer can be controlled. As a result, bulk layers of AlₓGa₁₋ₓAs_{z}P_{1-z}, preferably with a thickness greater than 0.1 microns and more preferably with a thickness greater than 0.2 microns, can be grown directly on GaAs or placed elsewhere within the structure in order to achieve an overall structure that is either flat or under a tensile stress, the later condition providing a means of minimizing or eliminating the effects of additional processing steps (e.g., the heat sink bonding procedure). FIG. 4 illustrates the range of available band-gaps and lattice constants (i.e., region 401) for AlₓGa₁₋ₓAs_{z}P_{1-z} relative to GaAs.

As shown in FIG. 4, there is a range of available lattice constants, thus allowing either flat structures to be fabricated or device designs that compensate for stress fields either within the structure or that result from an additional processing step (e.g., the heat sink bonding procedure). The inventors have also found that AlₓGa₁₋ₓAs_{z}P_{1-z} can be used as a means of compensating for other structural layers, for example a highly strained compressive quantum well.

It will be appreciated that the present invention lies in the use of one or more layers of AlₓGa₁₋ₓAs_{z}P_{1-z} within a device structure, these layers being selected to achieve a lattice match with GaAs. The invention is generally applicable to large area devices, for example those with an area greater that 0.25 square millimeters, and where the AlₓGa₁₋ₓAs_{z}P_{1-z} layers are greater than 0.1 microns thick, and preferably greater than 0.2 microns thick. Accordingly the invention is not limited to a specific structure, AlₓGa₁₋ₓAs_{z}P_{1-z} compound, or deposition technique.

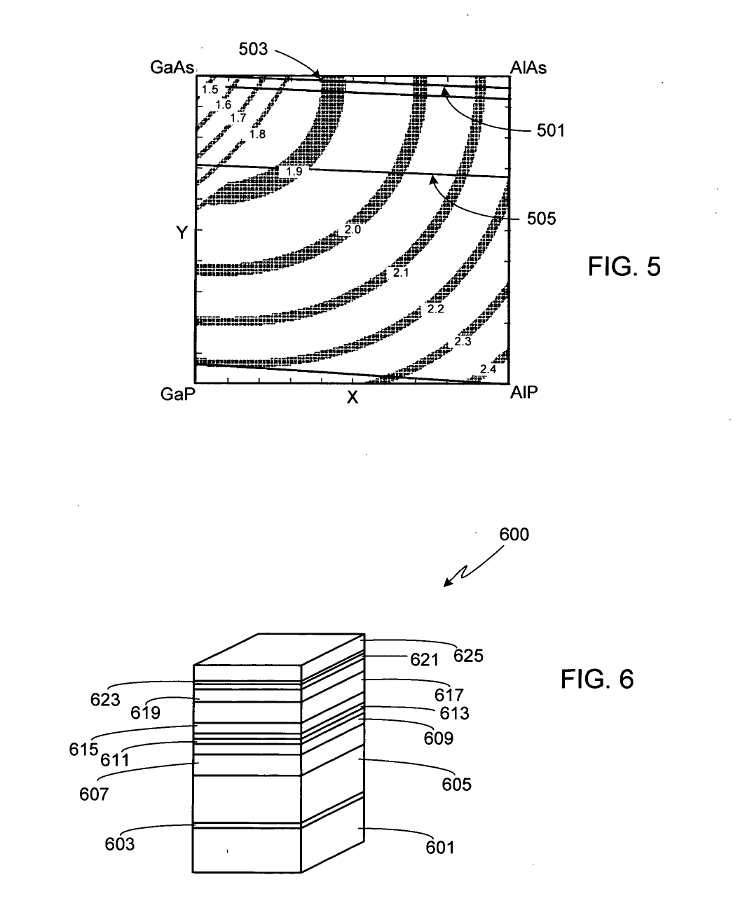

In general, the invention can either be used during the initial design phases of a device, or used to improve the performance of an existing design which utilizes one or more AlₓGa₁₋ₓAs layers and a GaAs substrate. In the first approach, the device is designed following normal design techniques, but utilizing layers of AlₓGa₁₋ₓAs_{z}P_{1-z} that are lattice matched to GaAs. In the second approach, each AlₓGa₁₋ₓAs layer within a structure is replaced with an AlₓGa₁₋ₓAs_{z}P_{1-z} layer of the same thickness and with the same concentration of Al and Ga. A small portion, less than 4 percent, of the As in the layer is replaced with P, thus achieving the desired lattice match with GaAs. The exact percentage of P added to the layer is based on the phase diagram for AlₓGa₁₋ₓAs_{z}P_{1-z} shown in FIG. 5. More specifically, the composition for the AlₓGa₁₋ₓAs_{z}P_{1-z} layer will fall on line 501. Data point 503 is an exemplary composition on line 501 consisting of Al_{0.4}Ga_{0.6}As_{0.985}P_{0.015}. It will be appreciated that if the percentage of phosphorous is increased further, the lattice mismatch between the AlₓGa₁₋ₓAs_{z}P_{1-z} compound and GaAs will impart a tensile strain to the resultant structure. For example, compositions lying on line 505 will have a 1 percent tensile strain, typically sufficient to compensate for a compressively strained layer or the stresses induced during heat sink bonding.

The material of the present invention, i.e., AlₓGa₁₋ₓAs_{z}P_{1-z}, can be used to replace AlₓGa₁₋ₓAs in any of a variety of structures in which it is desirable to control the stress within the layer, thereby creating a stressless structure. Furthermore it is possible to fabricate such layers/structures using any of a variety of techniques including metal organic chemical vapor phase epitaxy (MOCVD), molecular beam epitaxy (MBE), liquid phase epitaxy (LPE) and vapor phase epitaxy (VPE).

An exemplary semiconductor structure utilizing the invention, specifically a solar cell structure, is shown in FIG. 6. In addition to the layers shown in the figure, the structure also includes contact metallization layers and, preferably, anti-reflection coatings. Table I provides the composition and thickness of each of the individual layers of structure 600 assuming that the structure is fabricated in accordance with the prior art. Table II provides the composition and thickness of the individual layers of structure 600 assuming that the structure is fabricated in accordance with the invention, thus adding up to 4 percent of phosphorous to the AlₓGa₁₋ₓAs layers.

TABLE I

| | | Preferred | Range |
|---|---|---|---|
| Layer | Composition/Doping Level | Thickness (Å) | (μm) |
| 625 | GaAs 1e19 Zn doped | 1,000 | 0-1 |
| 623 | Al_{0.85}Ga_{0.15}As 1e18 Zn doped | 400 | 0-1 |
| 621 | Al_{0.36}Ga_{0.64}As 1e18 Zn doped | 700 | 0-1 |
| 619 | Al_{0.36}Ga_{0.64}As 1e15 Zn doped | 3,000 | 0-1 |
| 617 | Al_{0.36}Ga_{0.64}As 1e16 Si doped | 5,000 | 0-2 |
| 615 | Al_{0.6}Ga_{0.4}As 2e17 Si doped | 1,000 | 0-1 |
| 613 | GaAs 1e19 Si doped | 200 | 0-1 |
| 611 | GaAs 1e19 Zn doped | 100 | 0-1 |
| 609 | Al_{0.85}Ga_{0.15}As 1e18 Zn doped | 1,000 | 0-1 |
| 607 | GaAs 1e18 Zn doped | 5,000 | 0-2 |
| 605 | GaAs 8e16 Si doped | 35,000 | 0-10 |
| 603 | Al_{0.2}Ga_{0.8}As 5e17 Si doped | 1,000 | 0-1 |
| 601 | GaAs 5e17 Si doped | 40,000 | 0-10 |

TABLE II

| | | Preferred | Range |
|---|---|---|---|
| Layer | Composition/Doping Level | Thickness (Å) | (μm) |
| 625 | GaAs 1e19 Zn doped | 1,000 | 0-1 |
| 623 | Al_{0.85}Ga_{0.15}As_{0.968}P_{0.032} 1e18 Zn doped | 400 | 0-1 |
| 621 | Al_{0.36}Ga_{0.64}As_{0.988}P_{0.012} 1e18 Zn doped | 700 | 0-1 |
| 619 | Al_{0.36}Ga_{0.64}As_{0.988}P_{0.012} 1e15 Zn doped | 3,000 | 0-1 |
| 617 | Al_{0.36}Ga_{0.64}As_{0.988}P_{0.012} 1e16 Si doped | 5,000 | 0-2 |
| 615 | Al_{0.6}Ga_{0.4}As_{0.976}P_{0.024} 2e17 Si doped | 1,000 | 0-1 |
| 613 | GaAs 1e19 Si doped | 200 | 0-1 |
| 611 | GaAs 1e19 Zn doped | 100 | 0-1 |
| 609 | Al_{0.85}Ga_{0.15}As_{0.968}P_{0.032} 1e18 Zn doped | 1,000 | 0-1 |
| 607 | GaAs 1e18 Zn doped | 5,000 | 0-2 |
| 605 | GaAs 8e16 Si doped | 35,000 | 0-10 |
| 603 | Al_{0.2}Ga_{0.8}As_{0.996}P_{0.004} 5e17 Si doped | 1,000 | 0-1 |
| 601 | GaAs 5e17 Si doped | 40,000 | 0-10 |

For many solar cell applications, for example satellite arrays, the substrates undergo significant thinning in order to reduce the array weight. In a conventionally fabricated array such as that described in Table I, the residual stresses can lead to significant curvature in the array after completion of the substrate thinning procedure. The present invention (e.g., Table II) overcomes this problem.

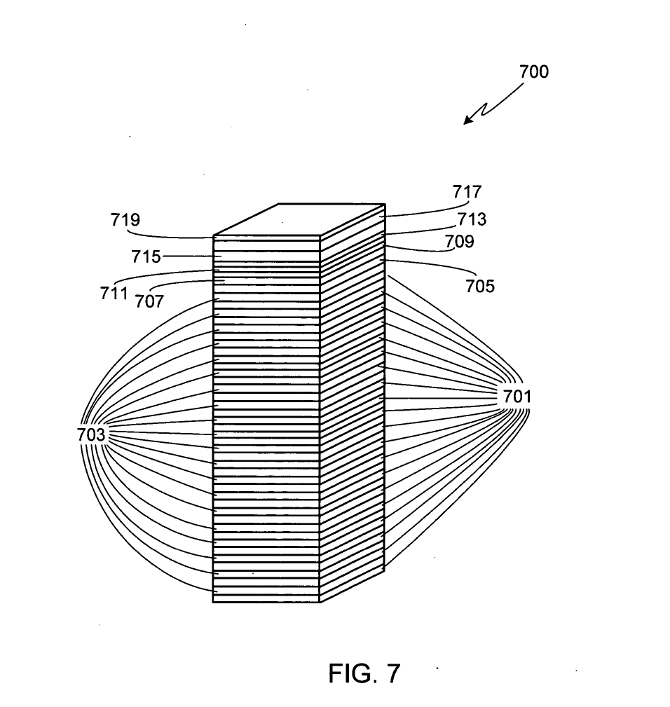

As previously noted, the present invention is not limited to a single type of semiconductor device. For example, another type of semiconductor device that can benefit from application of the present invention is an avalanche photo diode (APD) structure such as that shown in FIG. 7, such devices typically being used in large area arrays. Although not shown, the structure shown in FIG. 7 also includes contact metallization and anti-reflection coatings. During processing, the structure must also undergo device isolation processing. As with the previous example two tables are provided, one giving the compositions and thicknesses of the individual layers of a conventionally fabricated structure (Table III) and the other giving the compositions and thicknesses of the APD assuming the use of AlₓGa₁₋ₓAs_{z}P_{1-z} layers in accordance with the invention (Table IV). As in the previous example, the percentage of phosphorous in the AlₓGa₁₋ₓAs_{z}P_{1-z} layers (Table IV) will be less than 4 percent. Note that the compositions of layers 711 and 715 may be switched. Also note that the structure includes 20 layers each of AlAs (layer 701) and GaAs (layer 703).

TABLE III

| | | Preferred | Range |
|---|---|---|---|
| Layer | Composition/Doping Level | Thickness (Å) | (μm) |
| 719 | GaAs 1e19 Zn doped | 300 | 0-1 |
| 717 | Al_{0.2}Ga_{0.8}As 1e18 Si doped | 1,800 | 0-1 |
| 715 | Al_{0.2}Ga_{0.8}As | 1,200 | 0-1 |
| 713 | In_{0.1}Ga_{0.9}As | 300 | 0-1 |
| 711 | In_{0.1}Ga_{0.9}As | 500 | 0-1 |
| 709 | Al_{0.2}Ga_{0.8}As 1e18 Zn doped | 500 | 0-1 |
| 707 | Al_{0.2}Ga_{0.8}As | 1,000 | 0-1 |
| 705 | Al_{0.2}Ga_{0.8}As 4e18 Si doped | 5,000 | 0-2 |
| 703 | GaAs (×20) | 2,700 | 0-10 |
| 701 | AlAs (×20) | 2,700 | 0-10 |

TABLE IV

| | | Preferred | Range |
|---|---|---|---|
| Layer | Composition/Doping Level | Thickness (Å) | (μm) |
| 719 | GaAs 1e19 Zn doped | 300 | 0-1 |
| 717 | Al_{0.2}Ga_{0.8}As_{0.996}P_{0.004} 1e18 Si doped | 1,800 | 0-1 |
| 715 | Al_{0.2}Ga_{0.8}As_{0.996}P_{0.004} | 1,200 | 0-1 |
| 713 | In_{0.1}Ga_{0.9}As | 300 | 0-1 |
| 711 | In_{0.1}Ga_{0.9}As | 500 | 0-1 |
| 709 | Al_{0.2}Ga_{0.8}As_{0.996}P_{0.004} 1e18 Zn doped | 500 | 0-1 |
| 707 | Al_{0.2}Ga_{0.8}As_{0.996}P_{0.004} | 1,000 | 0-1 |
| 705 | Al_{0.2}Ga_{0.8}As_{0.996}P_{0.004} 4e18 Si doped | 5,000 | 0-2 |
| 703 | GaAs (×20) | 2,700 | 0-10 |
| 701 | AlAs_{0.96}P_{0.04} (×20) | 2,700 | 0-10 |

It will be understood that the detailed device structures described above are simply exemplary embodiments intended to demonstrate the application of the invention and are not intended to limit the scope of the invention to these particular structures. Once the benefits and the method of implementing the invention are understood, those of skill in the art will recognize that the invention can be implemented in other structures. In general terms, the inclusion of phosphorous in AlₓGa₁₋ₓAs can be used to achieve a strainless multi-layer design. Layers of AlₓGa₁₋ₓAs_{z}P_{1-z} can also be used to mitigate the compressive strain built into a structure due to layer material selection, metallization, surface dielectrics or polymers, or other processing steps.

As will be understood by those familiar with the art, the present invention may be embodied in other specific forms without departing from the spirit or essential characteristics thereof. Accordingly, the disclosures and descriptions herein are intended to be illustrative, but not limiting, of the scope of the invention which is set forth in the following claims.

What is claimed is:

1. A method of reducing the strain in a semiconductor device utilizing a GaAs substrate, wherein the semiconductor device has an area of at least 0.25 square millimeters and includes at least one AlₓGa₁₋ₓAs layer with a thickness of more than 0.2 microns, the method comprising the steps of:
replacing each of said at least one AlₓGa₁₋ₓAs layers with an AlₓGa₁₋ₓAs_{z}P_{1-z} layer during the fabrication of said semiconductor device; and
selecting a value for z such that a lattice constant of said AlₓGa₁₋ₓAs_{z}P_{1-z} layer matches a lattice constant of said GaAs substrate.

2. The method of claim 1, further comprising the step of selecting a thickness for each of said AlₓGa₁₋ₓAs_{z}P_{1-z} layers which is equivalent to a layer thickness of the AlₓGa₁₋ₓAs layer that said AlₓGa₁₋ₓAs_{z}P_{1-z} layer replaces.

3. A method of fabricating a semiconductor device, the method comprising the steps of:
selecting GaAs as the substrate for said semiconductor device;
selecting a substrate area of greater than 0.25 square millimeters; and
growing at least one AlₓGa₁₋ₓAs_{z}P_{1-z} layer on said substrate, said AlₓGa₁₋ₓAs_{z}P_{1-z} layer growing step comprising the steps of:
selecting an AlₓGa₁₋ₓAs_{z}P_{1-z} layer area of greater than 0.25 square millimeters;
selecting an AlₓGa₁₋ₓAs_{z}P_{1-z} layer thickness of greater than 0.1 microns; and
matching an AlₓGa₁₋ₓAs_{z}P_{1-z} layer lattice constant with a GaAs lattice constant.

4. The method of claim 3, further comprising the step of growing at least one non-AlₓGa₋₁ₓAs_{z}P_{1-z} layer on said substrate.

5. The method of claim 4, further comprising the step of interposing said at least one non-AlₓGa₁₋ₓAs_{z}P_{1-z} layer between said substrate and said AlₓGa₁₋ₓAs_{z}P_{1-z} layer.

6. A semiconductor device comprising:
a GaAs substrate with an area of greater than 0.25 square millimeters; and
at least one AlₓGa₁₋ₓAs_{z}P_{1-z} layer with a layer thickness greater than 0.2 microns and a lattice constant that matches a lattice constant of said GaAs substrate.
